(19) United States
(12) Patent Application Publication
(10) Pub. No.: US 2026/0267241 A1
(43) Pub. Date: Sep. 10, 2026

(54) EUV RADIATION ENERGY SENSOR

(71) Applicant: ASML NETHERLANDS B.V., Veldoven (NL)

(72) Inventors: Lei LIANG; Juan SHAN; Tian GANG

(21) Appl. No.: 19/491,369

(22) PCT Filed: Jul. 4, 2024
(86) PCT No.: PCT/EP2024/068843

§ 371 Date: Dec. 8, 2025

(30) Foreign Application Priority Data
Jul. 19, 2023 (EP) 23186451.3

(51) Int. Cl. G03F 7/00

(52) U.S. Cl. CPC G03F 7/70875; G03F 7/70716

(57) ABSTRACT

A sensor for measuring energy of EUV radiation from combined radiation including EUV radiation and non-EUV radiation, the sensor including: a radiation absorber configured to absorb radiation derived from the combined radiation via a surface of the radiation absorber; a first reflector having a first reflectivity to EUV radiation configured to modify the combined radiation entering the surface; a second reflector having a second reflectivity to EUV radiation configured to modify the combined radiation entering the surface, the second reflectivity being different from the first reflectivity; a thermometer configured to measure a temperature change of the radiation absorber; and a calculator configured to calculate the energy of EUV radiation based on a first temperature change associated with the combined radiation modified by the first reflector and a second temperature change associated with the combined radiation modified by the second reflector.

### CROSS-REFERENCE TO RELATED APPLICATIONS

This application claims priority of EP Application Serial No. 23186451.3 which was filed on 19 Jul. 2023 and which is incorporated herein in its entirety by reference.

### FIELD

The present invention relates to a sensor for measuring energy of EUV radiation, a substrate table, an EUV lithographic apparatus and a method of measuring energy of EUV radiation.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

It is desirable to know the dose of EUV radiation that is being used. The radiation beam of the electromagnetic radiation may include some non-EUV radiation as well as the EUV radiation. This can make it more difficult to measure the energy of the EUV radiation.

### SUMMARY

An object of the invention is to measure the energy of EUV radiation more accurately.

According to an aspect, there is provided a sensor for measuring energy of EUV radiation from combined radiation comprising EUV radiation and non-EUV radiation, the sensor comprising: a radiation absorber configured to absorb radiation derived from the combined radiation via a surface of the radiation absorber; a first reflector having a first reflectivity to EUV radiation configured to modify the combined radiation entering the surface; a second reflector having a second reflectivity to EUV radiation configured to modify the combined radiation entering the surface, the second reflectivity being different from the first reflectivity; a thermometer configured to measure a temperature change of the radiation absorber; and a calculator configured to calculate the energy of EUV radiation based on a first temperature change associated with the combined radiation modified by the first reflector and a second temperature change associated with the combined radiation modified by the second reflector.

According to another aspect, there is provided a method for measuring energy of EUV radiation from combined radiation comprising EUV radiation and non-EUV radiation, the method comprising: modifying the combined radiation entering a surface of a radiation absorber with a first reflector having a first reflectivity to EUV radiation; measuring a first temperature change of the radiation absorber associated with the combined radiation modified by the first reflector; modifying the combined radiation entering the surface with a second reflector having a second reflectivity to EUV radiation, the second reflectivity being different from the first reflectivity; measuring a second temperature change of the radiation absorber associated with the combined radiation modified by the second reflector; and calculating the energy of EUV radiation based on the first temperature change and the second temperature change.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2 schematically depicts a sensor for measuring energy of EUV radiation;

FIG. 3 schematically depicts a plan view of part of the sensor;

FIG. 4 schematically depicts layers of a reflector of the sensor;

FIGS. 5 and 6 schematically depict gratings of a reflector; and

FIG. 7 schematically depicts a plan view of a substrate table comprising the sensor.

### DETAILED DESCRIPTION

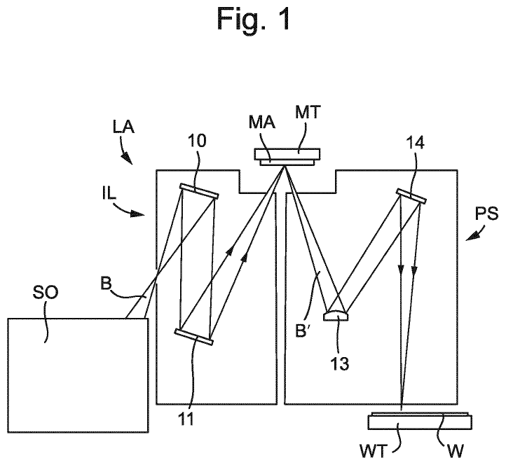

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

In an embodiment the lithographic apparatus LA comprises at least one sensor 20. The sensor 20 is for measuring energy of EUV radiation. The sensor 20 is for measuring the energy of the radiation of the EUV radiation beam B or the patterned EUV radiation B′ associated with EUV radiation (e.g. radiation having a wavelength within the range 4-20 nm). The radiation beam B and the patterned EUV radiation beam B′ may comprise combined radiation 15 including both EUV radiation and non-EUV radiation. The sensor 20 is for measuring energy associated with the EUV radiation component of the combined radiation.

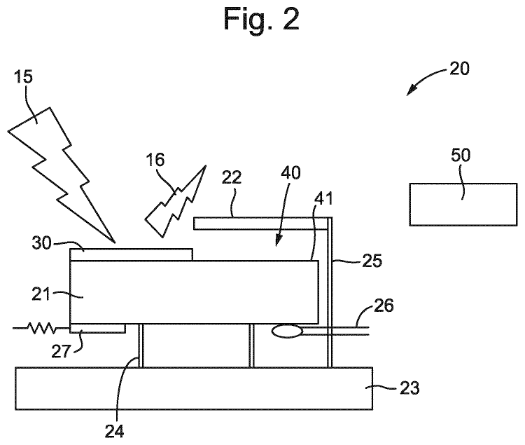

FIG. 2 schematically depicts an embodiment of the sensor 20. As shown in FIG. 2, in an embodiment the sensor 20 comprises a radiation absorber 21. The radiation absorber 21 is configured to absorb radiation derived from the combined radiation 15 via a surface 40 of the radiation absorber 20. In an embodiment the surface 40 of the radiation absorber 21 is a surface 40 facing the incoming combined radiation 15. As shown in FIG. 2, in an embodiment the surface 40 is an upper surface of the radiation absorber 21. Alternatively, the surface 40 may be a side surface or a bottom surface, for example, of the radiation absorber 21, depending on the position/orientation of the radiation absorber 21 with respect to the incoming combined radiation 15.

In an embodiment the sensor 20 is a calorimetric sensor for measuring an EUV radiation impinged on the sensor 20. In an embodiment the radiation absorber 21 comprises a substrate. The radiation absorber 21 may be referred to as an EUV absorber. The radiation absorber 21 is configured to absorb the EUV radiation and convert it to heat. In an embodiment the radiation absorber 21 is made of high thermal conductivity, low thermal capacity material to maximize its responsivity.

In an embodiment the radiation absorber 21 comprises a material having high thermal conductivity. For example, the radiation absorber 21 may comprise a material having a thermal conductivity of at least 5 W/m/K, optionally at least 10 W/m/K, optionally at least 20 W/m/K, optionally at least 50 W/m/K, optionally at least 100 W/m/K, optionally at least 200 W/m/K, optionally at least 500 W/m/K, optionally at least 1000 W/m/K and optionally at least 2000 W/m/K. By providing that the radiation absorber 21 has a high thermal conductivity, heat absorbed through the surface 40 may transfer throughout the bulk of the radiation absorber 21 relatively quickly, such that the radiation absorber 21 has a relatively consistent temperature throughout its bulk. This may help to increase the accuracy of measurements of temperature rises of the radiation absorber 21.

In an embodiment the radiation absorber 21 comprises a material having a low thermal capacity. In an embodiment the radiation absorber 21 comprises a material having a heat capacity of at most 1500 J/kg/K, optionally at most 2000 J/kg/K and optionally at most 1000 J/kg/K. By providing that the radiation absorber 21 has a low thermal capacity, a greater temperature change of the radiation absorber 21 may be detected for a given energy of EUV radiation absorbed via the surface 40. This may help to increase the accuracy by which the energy absorbed by the radiation absorber 21 may be measured.

In an embodiment the radiation absorber 21 comprises a material selected from the group consisting of graphene and titanium carbide (Ti₃C₂).

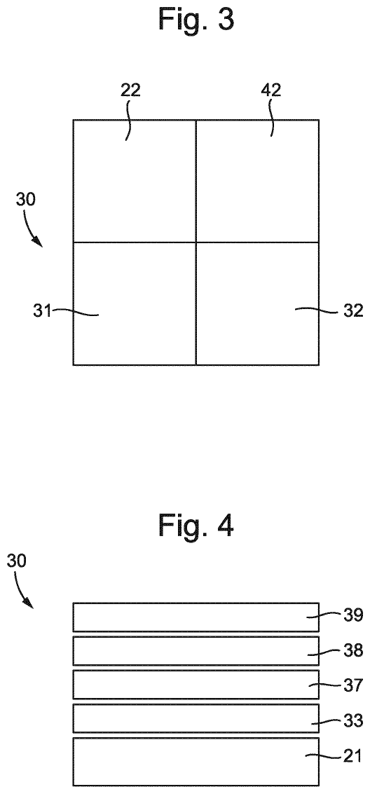

As shown in FIG. 2, in an embodiment the sensor 20 comprises reflectors 30. FIG. 3 schematically depicts a plan view of part of the sensor 20 from above the radiation absorber 21. As shown in FIG. 3, in an embodiment the reflectors 30 comprise a first reflector 31 and a second reflector 32. In an embodiment the first reflector 31 has a first reflectivity to EUV radiation. The reflectivity refers to the proportion of EUV radiation that is reflected by the reflector. A higher reflectivity means that a higher proportion of the EUV radiation that is incident on the reflector is reflected by the reflector. The reflectors 30 may be provided at the surface 40 of the radiation absorber 21. Alternatively, the reflectors 30 may be located near to the surface 40. In an embodiment the reflectors 30 comprise reflective gratings.

As shown in FIG. 2, the reflectors 30 are configured to reflect EUV radiation from the combined radiation 15 such that reflected radiation 16 is directed away from the reflectors 30. The first reflector 31 is configured to modify the combined radiation 15 entering the surface 40. In an embodiment the first reflector 31 is configured to transmit a proportion of the EUV radiation of the combined radiation 15. This proportion of the EUV radiation that is transmitted by the first reflector 31 enters the radiation absorber 21 via the surface 40. In an embodiment the first reflector 31 is configured to reflect substantially all of the non-EUV radiation of the combined radiation 15. For example, in an embodiment the first reflector 31 is configured to reflect at least 99%, optionally at least 99.9%, and optionally at least 99.99% of the non-EUV radiation of the combined radiation 15. In an embodiment the non-EUV radiation comprises infrared (IR) radiation. In an embodiment the reflectors 30 are configured to reflect radiation with spectra other than EUV wavelength (e.g 13.5 nm).

In an embodiment the sensor 20 comprises a second reflector 32. The second reflector 32 has a second reflectivity to EUV radiation. Otherwise, the second reflector 32 may have a similar function to the first reflector 31. In an embodiment the second reflector 32 is configured to modify the combined radiation 15 entering the surface 40. The reflectivity is different from the first reflectivity. The first and second reflectors 31, 32 are arranged to reflect different proportions of EUV radiation from the combined radiation 15. In an embodiment the second reflector 32 is configured to transmit a proportion of the EUV radiation of the combined radiation 15 into the surface 40 of the radiation absorber 21. In an embodiment, the second reflector 32 is configured to reflect substantially all of the non-EUV radiation of the combined radiation 15. For example, in an embodiment the second reflector 32 is configured to reflect at least 99%, optionally at least 99.9% and optionally at least 99.99% of the non-EUV radiation of the combined radiation 15.

In an embodiment the combined radiation 15, which may be radiation of the EUV radiation beam B or the patterned EUV radiation B′, is directed toward a portion of the radiation absorber 21 corresponding to one of the first reflector 31 and the second reflector 32. In an embodiment the reflectors 30 are provided at the surface 40 of the radiation absorber 21. The reflectors 30 may be provided immediately upbeam (i.e. upstream) of the surface 40. The reflectors 30 are located between the radiation absorber 21 and the incoming combined radiation 15. The reflectors 30 are arranged such that the combined radiation 15 is incident on one of the reflectors 30 before the modified radiation enters the radiation absorber 21 via the surface 40. The reflectors 30 may be provided as one or more layers on the surface 40 of the radiation absorber 21.

In an embodiment, the combined radiation 15 may be directed onto one of the reflectors 30 at a time. When the combined radiation 15 is directed onto the first reflector 31, the EUV radiation that is transmitted by the first reflector 31 enters the radiation absorber 21 so as to heat the radiation absorber 21. At this time, the combined radiation 15 is not directed onto the second reflector 32. In another mode of operation, the combined radiation 15 is directed onto the second reflector 32. The EUV radiation that is transmitted by the second reflector 32 enters the radiation absorber 21 via the surface 40 so as to heat the radiation absorber 21. When the combined radiation 15 is directed onto the second reflector 32, the combined radiation 15 is not directed onto the first reflector 31.

As shown in FIG. 2, in an embodiment the sensor 20 comprises a thermometer 26. In an embodiment the thermometer 26 is configured to measure a temperature change of the radiation absorber 21. The temperature change may be associated with (e.g. caused by) the radiation absorbed by the radiation absorber 21. By measuring the temperature change of the radiation absorber 21, the energy that is absorbed by the radiation absorber 21 may be measured. In an embodiment the thermometer 26 comprises a thermistor. In an embodiment the thermometer 26 is located at the backside of the radiation absorber 21.

In an embodiment the sensor 20 comprises a calculator. As shown in FIG. 2, in an embodiment a controller 50 is provided. In an embodiment the sensor 20 comprises the controller 50. Alternatively, the controller 50 may be provided as a separate component from the sensor 20. In an embodiment the controller 50 is configured to control the sensor 20. In an embodiment the controller 50 comprises the calculator. Alternatively, the calculator may be provided as a separate component.

In an embodiment the calculator is configured to calculate the energy of EUV radiation. In an embodiment the calculator is configured to calculate the energy of EUV radiation based on a first temperature change associated with the combined radiation modified by the first reflector 31 and a second temperature change associated with the combined radiation 15 modified by the second reflector 32. As mentioned elsewhere, the first reflector 31 and the second reflector 32 have different reflectivity to EUV radiation. As a result, the first reflector 31 and the second reflector 32 transmit different proportions of the combined radiation 15 into the radiation absorber 21. By measuring how the temperature change of the radiation absorber 21 varies depending on the proportion of transmitted EUV radiation, the energy of the EUV radiation of the combined radiation 15 may be determined.

The dose of EUV radiation is correlated with the temperature change of the radiation absorber 21. The temperature change of the radiation absorber 21 is an intrinsic physical parameter that can be measured accurately. An embodiment of the invention is expected to increase the accuracy with which energy of EUV radiation can be measured.

EUV radiation is easily absorbed by a solid. When the EUV radiation is absorbed by the radiation absorber 21, the EUV radiation is converted to heat. The efficiency of conversion from the EUV radiation to heat depends on the properties of the material of the radiation absorber 21.

An embodiment of the invention is expected to improve the reliability of measurement of energy of EUV radiation. An alternative way of measuring the energy of EUV radiation would be to use a band pass filter to filter out non-EUV radiation. The temperature change caused by the transmitted EUV radiation could then be used to measure the transmitted EUV radiation. If the proportion of EUV radiation transmitted by the band pass filter is known, then the energy of EUV radiation of the combined radiation may be calculated. It is possible that such a band pass filter may change over time. Properties of the band pass filter may be altered, for example as a result of the combined radiation incidence upon it. Such degradation can affect the properties such as the proportion of EUV radiation transmitted by the band pass filter. This can lead to the measurement of the energy becoming less accurate. By providing the reflectors 30, the reflectors 30 may degrade less and/or differently compared to such a band pass filter. The measurement of the energy of EUV radiation using the reflectors 30 may help to avoid the inaccuracies introduced by the degradation of the band pass filter.

In an embodiment the calculator is configured to calculate the energy of EUV radiation based on the first temperature change, the first reflectivity, the second temperature change and the second reflectivity. In an embodiment, the energy of EUV radiation may be directly proportional to a difference between the first temperature change and the second temperature change. In an embodiment the energy of EUV radiation may be inversely proportional to a difference between the first reflectivity and the second reflectivity. In an embodiment the energy E_{inband} of EUV radiation can be calculated using the following formula.

$${E}_{inband} = \frac{Q 2 - Q 3}{( 1 - β1 ) - ( 1 - β2 )} = \frac{Q 2 - Q 3}{β2 - β1}$$

where Q2 is the heat converted from the modified radiation transmitted through the first reflector 31, Q3 is the heat converted from the modified radiation transmitted through the second reflector 32, β2 is the reflectivity to EUV radiation of the second reflector 32 and β1 is the reflectivity to EUV radiation of the first reflector 31.

As shown in the formula, in an embodiment the measurement of the energy of EUV radiation depends on the difference between the first reflectivity and the second reflectivity. It may not be necessary to know the absolute values of the first reflectivity and second reflectivity. If the first reflector 31 and the second reflector 32 degrade such that the first reflectivity and the second reflectivity change at a similar rate, then the calculation of the energy of EUV radiation may remain relatively accurate even as the reflectors 30 degrade over time. An embodiment of the invention is expected to improve the accuracy of measurement of EUV radiation over longer periods of time.

In an embodiment, the measured heat is directly proportional to the temperature change. In particular, the heat Q may be related to the temperature rise ΔT according to the following equation.

Q=CmΔT where C is the thermal capacity (specific heat capacity) of the radiation absorber 21 and m is the mass of the radiation absorber 21.

As explained elsewhere, the first reflectivity is different from the second reflectivity. The first reflector 31 has different properties from the second reflector 32. The first reflector 31 and the second reflector 32 are arranged differently from each other so as to have different reflectivity to EUV radiation. In an embodiment, the first and second reflectors 31, 32 comprise different topologies. Different topologies can result in different reflectivity to EUV radiation.

FIG. 4 is a schematic view of reflectors 30 of the sensor 20. As shown in FIG. 4, in an embodiment the reflectors 30 comprise a plurality of layers. The layers may be layered on top of each other in a stack. As shown in FIG. 4, the layers of the reflectors 30 may be layered on top of the radiation absorber 21. As shown in FIG. 4, in an embodiment the reflectors 30 comprise a grating 33. In an embodiment the first and second reflectors 31, 32 comprise respective gratings 33. The gratings 33 may comprise different topologies. Alternatively, the first and second reflectors 31, 32 may comprise equivalent, (substantially the same) gratings 33. The difference in reflectivity to EUV radiation may be provided by a different layer of the reflectors 30 compared to the grating 33.

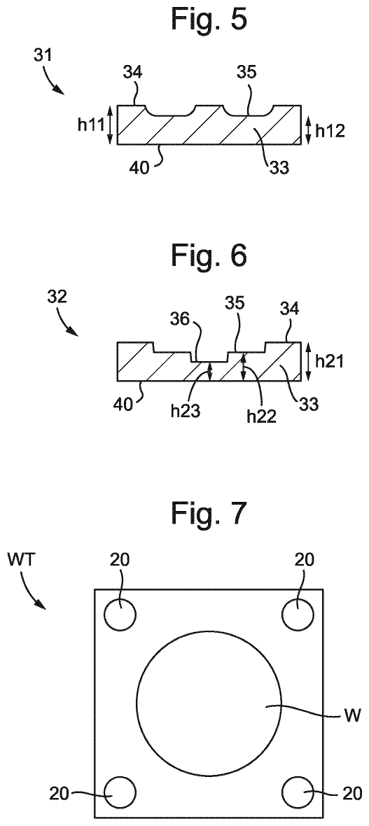

FIG. 5 schematically depicts a grating 33 of the first reflector 31. FIG. 6 schematically depicts a grating 33 of the second reflector 32. As shown from a comparison of FIGS. 5 and 6, the grating 33 of the first reflector 31 may be different from the grating 33 of the second reflector 32. In an embodiment the grating 33 has a thickness of at least one micron, optionally at least two microns and optionally at least five microns. In an embodiment the grating 33 has a thickness of at most ten microns, optionally at most five microns and optionally at most two microns. In an embodiment the grating 33 is applied to the surface 40 of the radiation absorber 21. For example, in an embodiment a material that forms the grating 33 may be sputtered onto the radiation absorber 21. The material of the grating 33 may subsequently be shaped, for example by an etching process.

As shown in FIG. 5 and FIG. 6, in an embodiment the gratings 33 comprise a plurality of levels 34-36. Each level corresponds to a different distance from the surface 40 of the radiation absorber 21. As shown in FIG. 5, in an embodiment the grating 33 of the first reflector 31 comprises two levels 34, 35. A first level 34 is a first distance h11 from the surface 40. The second level 35 is a second distance h12 from the surface 40. The grating 33 may be referred to as a two-level grating.

As shown in FIG. 6, in an embodiment, the second reflector 32 comprises a grating 33 comprising three levels 34-36. The grating 33 comprises a first level 34 which is a first distance h21 from the surface 40. The grating 33 comprises a second level 35 which is a second distance h22 from the surface 40. A third level 36 is a third distance h23 from the surface 40. By providing the plurality of levels at different distances from the surface 40, a deflection grating is provided so as to reflect proportions of radiation. As shown in FIGS. 5 and 6, the respective gratings 33 may comprise different numbers of levels. In the arrangements shown, the first reflector 31 comprises a grating 33 having two levels, while the second reflector 32 comprises a grating 33 comprising three levels 34-36. The grating 33 of the second reflector 32 may be referred to as three-level grating. By providing different numbers of levels, the properties of the reflectors 30 may be different from each other.

IR suppression efficiency of a multi-level diffractive lens is a function of the number of levels (which may be referred to as steps). Analogously, a reflector comprising a three-level grating may be expected to have an increased the EUV reflection rate compared to a reflector comprising a two-level grating. The theoretical maximum reflection rate for a two-level grating may be 41%. The theoretical maximum reflection rate for a three-level grating may be 68%. The in-band EUV reflectivity of the reflectors 30 may be calibrated and may be in the range of 30-70%.

As shown in FIG. 4, in an embodiment the reflectors 30 comprise a reflective layer 38. The reflective layer comprises a material configured to reflect a proportion of incident EUV radiation and transmit a proportion of EUV radiation. In an embodiment the reflective layer 38 is configured as an EUV mirror. in an embodiment the reflective layer comprises a plurality of layers. The reflective layer 35 may comprise alternating layers of different materials. For example, in an embodiment the reflective layer 38 comprises alternating layers of silicon and molybdenum. In an embodiment the reflective layer 38 has a thickness of at least 15 nm, optionally at least 100 nm, optionally at least 200 nm, optionally at least 500 nm, optionally at least 1 μm, optionally at least 2 μm and optionally at least 5 μm. In an embodiment the reflective layer 38 has a thickness of at most 10 μm, optionally at most 5 μm, optionally at most 2 μm, optionally at most 1 μm, optionally at most 500 nm, optionally at most 200 nm. In an embodiment each layer within the reflective layer 38 has a thickness of at least 2 nm and optionally at least 5 nm. In an embodiment each layer within the reflective layer 38 has a thickness of at most 20 nm, optionally at most 10 nm and optionally at most 5 nm.

By providing the grating layer 33 between the reflective layer 38 and the radiation absorber 21, the reflective layer 38 is shaped in accordance with the grating 33. By shaping the reflective layer 38 according to the grating 33, the reflectivity of the reflective layer 38 may be controlled. The reflective layer 38 of the first reflector 31 may be shaped differently from the reflective layer 38 of the second reflector 32. This difference in shape of the reflective layers 38 may result in the first reflector 31 and the second reflector 32 having different reflectivity to UV radiation.

In an embodiment, the EUV reflection layers 38 of the first and second reflectors 31, 32 may have a similar (optionally the same) composition. The EUV reflection layers 38 may be formed of the same material. In an embodiment the reflection layers 38 of the first and second reflectors 31, 32 may have the same thickness as each other. The difference in reflectivity may be due to the difference in shape caused by the different gratings 33.

Alternatively, the EUV reflection layer 38 of the first reflector 31 may have a different thickness compared to the EUV reflection layer 38 of the second reflector 32. By providing different thicknesses of the EUV reflection layers 38, the first reflectivity may be different from the second reflectivity. In an embodiment the EUV reflection layers 38 of the first and second reflectors 31, 32 may be shaped in substantially the same way. For example, the gratings 33 of the first and second reflectors 31, 32 may be substantially the same.

As shown in FIG. 4, in an embodiment the reflectors 30 comprise a buffer layer 37. The buffer layer 37 may be configured to improve fixation of the EUV reflection layer 38 onto the grating 33. For example, in an embodiment a lattice constant of a material of the buffer layer 37 may have an intermediate value between a lattice constant of the material of the grating 33 and a lattice constant of a material of the EUV reflection layer 38. The material of the grating 33 may be selected so as to provide good fixation to the radiation absorber 21. In an embodiment the buffer layer 37 has a thickness of at least 1 μm, optionally at least 2 μm, optionally at least 5 μm, optionally at least 10 μm, optionally at least 20 μm and optionally at least 50 μm. In an embodiment the buffer layer 37 has a thickness of at most 100 μm, optionally at most 50 μm, optionally at most 20 μm, optionally at most 10 μm, optionally at most 5 μm and optionally at most 2 μm.

As shown in FIG. 4, in an embodiment the reflectors 30 comprise a capping layer 39. The capping layer 39 is configured to protect the EUV reflection layer 38. For example, in an embodiment the capping layer 39 is configured to reduce out-gassing of the EUV reflection layer 38. In an embodiment the capping layer 39 is configured to reduce etching of the EUV reflection layer 38 during use of the sensor 20. In an embodiment the capping layer 39 has a thickness of at least 10 nm, optionally at least 20 nm and optionally at least 50 nm. In an embodiment the capping layer 39 has a thickness of at most 100 nm and optionally at most 50 nm.

In an embodiment the reflectors 30 comprise reflective gratings comprising a capping layer 39, an EUV reflection layer 38, a buffer layer 37 and a grating 33. In an embodiment the purpose of the reflective grating is to maximize the reflection of EUV while keeping almost all out-of-band (mainly IR) being absorbed.

As shown in FIG. 2, in an embodiment the sensor 20 comprises a heater 27. The heater 27 may be a thermal heater, for example a resistive heater. Alternative types of heaters may be used. As shown in FIG. 2, the heater 27 is coupled to the radiation absorber 21. The heater 27 is configured to heat the radiation absorber 21. In an embodiment the heater 27 is configured to heat the radiation absorber 21 independently of the combined radiation 15.

In an embodiment the heater 27 is a thermal resistor heater 27. The heater 27 may be configured to heat the radiation absorber 21 for a calibration purpose. The heater 27 may be calibrated with a well-defined power, so that with a given amount of time, the total input energy (in Joules) is known. In an embodiment the controller 50 is configured to control the heater 27 to vary its power within a range of from about 0.001 W/mm² to about 0.1 W/mm² at 70° C.

In an embodiment the controller 50 is configured to operate the sensor 20 in a calibration mode. In the calibration mode, the controller 50 is configured to control the heater 27 to heat the radiation absorber 21. During this time, the combined radiation 15 is not directed onto the radiation absorber 21. The heating up of the radiation absorber 21 is caused by the heat input by the heater 27.

In an embodiment the calculator is configured to calibrate calculation of the energy of EUV radiation based on heat output by the heater 27 and a calibration temperature change associated with the heat from the heater 27. In an embodiment the thermometer 26 is configured to measure the calibration temperature change. The calibration temperature change is the temperature change of the radiation absorber 21 as a result of the heat input by the heater 27.

In an embodiment the heat output by the heater 27 may be known. For example, when the heater 27 is a thermal resistor heater, then the injected energy Q5 may be related to the current I and resistance R and time using the following formula.

Q5=I²Rt where t is the time for which the heater 27 outputs heat to the radiation absorber 21.

Meanwhile, the heat Q5 is associated with the temperature change ΔT by the following formula.

Q5=CmΔT where C is the thermal capacity (specific heat capacity) of the radiation absorber 21 and m is the mass of the radiation absorber 21.

By using these two formulae, the heat capacity and mass of the radiation absorber 21 may be calibrated. For example, during use of the sensor, the radiation absorber 21 may reduce in mass. By performing a calibration, the accuracy of measurement of energy of EUV radiation may be improved.

The calibration process is to update the Cm term and take the new value into future measurement processes. The Cm term may be determined by the following formula.

Cm=I²Rt/ΔT where I is the current of the heater 27, R is the resistance of the heater 27, t is the time for which the heater 27 outputs heat to the radiation absorber 21 and ΔT is the temperature change caused by the heater 27.

As shown in FIG. 2, in an embodiment the sensor 20 comprises an EUV filter 22. The EUV filter 22 is different from the first reflector 31 and the second reflector 32. In an embodiment the EUV filter 22 is configured to filter out the non-EUV radiation from the combined radiation 15 such that filtered radiation is incident on a filter portion 41 of the surface 40. The filter portion 41 is a portion of the surface 40 of the radiation absorber 21 on which the radiation is incident after having passed through the EUV filter 22. As shown in FIG. 2, in an embodiment the filter portion 41 is directly below the EUV filter 22.

In an embodiment the EUV filter 22 is a bandpass filter. In an embodiment the EUV filter 22 comprises a material selected from a group consisting of Zr, poly-Si and multilayers comprising Zr and poly-Si. In an embodiment the EUV filter 22 is configured to have a high in-band EUV transmission rate up to 76% and to filter off most out-of-band (including IR) spectra to below 0.01%.

As shown in FIG. 2, in an embodiment the EUV filter 22 is distanced from the radiation absorber 21. This is different from the position of the reflectors 30 which are in physical contact with the surface 40. The EUV filter 22 is separated from the radiation absorber 21. There may be a gap between the EUV filter 22 and the surface 40 of the radiation absorber 21. In an embodiment, the EUV filter 22 is configured to absorb some of the combined radiation 15. For example, the EUV filter 22 may absorb the non-EUV radiation. By distancing the EUV filter 22 from the radiation absorber 21, the possibility of the non-EUV radiation undesirably heating up the radiation absorber 21 may be reduced.

In an embodiment the calculator is configured to calculate the energy of EUV radiation based on a filter temperature change associated with the filtered radiation. The filtered temperature change is the change in temperature of the radiation absorber 21 as a result of incident radiation that has passed through the EUV filter 22. In an embodiment, the combined radiation 15 is directed onto the EUV filter 22 so that the filtered radiation heats up the radiation absorber 21. When the combined radiation 15 is directed onto the EUV filter 22, the EUV radiation may not be directed onto the reflectors 30.

In an embodiment the thermometer 26 is configured to measure the filter temperature change associated with the filtered radiation. The rise in temperature is measured by the thermometer 26 and that measures the temperature of the bulk of the surface of the radiation absorber 21. By measuring the filter temperature change, the heat derived from the filtered radiation may be determined. When the EUV transmission rate (the proportion of EUV radiation that is transmitted through the EUV filter 22) is known, the energy E_{inband} of EUV radiation of the combined radiation 15 may be calculated using the following formula.

$${E}_{inband} = \frac{Q 1}{α}$$

where Q1 is the heat converted from the filtered radiation transmitted through the EUV filter 22 and a is the proportion of EUV radiation transmitted by the EUV filter 22.

The energy of the EUV radiation may be calculated independently based on measurements of radiation incident on the reflectors 30 and radiation incident on the EUV filter 22. This helps to verify the measurement of the EUV radiation. This may help to determine the extent to which the reflectors 30 or the EUV filter 22 are degrading over time. Additionally or alternatively, the energy of the EUV radiation may be calculated based on an average (e.g. a mean) of the two ways of determining the energy of the EUV radiation.

As shown in FIG. 3, in an embodiment the first reflector 31, the second reflector 32 and the EUV filter 22 correspond to different portions (e.g. different quadrants) of the surface of the radiation absorber 21. As shown in FIG. 3, in an embodiment the sensor 20 is arranged such that the combined radiation 15 may be incident on an exposed portion 42 of the surface 40. The exposed portion 42 is not covered by a reflector or an EUV filter. The exposed portion 42 may receive the combined radiation 15 unmodified. The exposed portion 42 may be referred to as a bare portion. As shown in FIG. 3, in an embodiment the exposed portion 42 corresponds to a portion (e.g. a quadrant) of the surface 40 of the radiation absorber 21. In an embodiment the sensor top surface consists of four elements, which are substantially equal in size. The exposed portion 42 may be used for comparison.

In an embodiment, the calculator is configured to calculate energy of the non-EUV radiation based on a bare temperature change associated with the combined radiation 15 incident on the exposed portion 42 of the surface 40. The bare temperature change is the temperature change of the radiation absorber 21 caused by the combined radiation 15 absorbed through the exposed portion 42 of the surface 40 of the radiation absorber 21. In an embodiment the combined radiation 15 may be directed onto the exposed portion 42. When the combined radiation 15 is directed onto the exposed portion 42, the combined radiation 15 may be directed such that it is not incident on the EUV filter 22 or the reflectors 30.

By measuring the bare temperature change, the heat resulting from the unmodified combined radiation 15 may be determined. This may allow the energy E_{OOB} of the non-EUV radiation of the combined radiation 15 to be determined using one or both of the following equations.

$${E}_{OOB} = Q 4 - \frac{Q 2 - Q 3}{β2 - β1}$$

where Q4 is the heat converted from the combined radiation 15 incident on the exposed portion 42, Q2 is the heat converted from the modified radiation transmitted through the first reflector 31, Q3 is the heat converted from the modified radiation transmitted through the second reflector 32, β2 is the reflectivity to EUV radiation of the second reflector 32 and β1 is the reflectivity to EUV radiation of the first reflector 31.

$${E}_{OOB} = Q 4 - \frac{Q 1}{α}$$

on the exposed portion 42, Q1 is the heat converted from the filtered radiation transmitted through the EUV filter 22 and a is the proportion of EUV radiation transmitted by the EUV filter 22.

In an embodiment the energy of the non-EUV radiation may be determined based on a combination (e.g an average such as a mean) of the two methods of determining the energy of the non-EUV radiation.

In an embodiment the first reflector 31 is provided at a first reflector region of the surface 40 and the second reflector 32 is provided at a second reflector region of the surface 40. The first reflector region and the second reflector region do not overlap with each other. As shown in FIG. 3, in an embodiment the first reflector 31 and the second reflector 32 do not overlap each other. The first reflector 31 may be adjacent to the second reflector 32. It is not essential for the EUV filter 22 to be provided. The energy of EUV radiation may be determined without the EUV filter 22. It is not essential for the exposed portion 42 to be provided. In an alternative embodiment, the reflectors 30 and optionally the EUV filter 22 if it is provided covers substantially all of the surface 40 of the radiation absorber 21.

During use of the sensor 20, one of the four elements can be illuminated using a mask (e.g. blades) to shield the incident light to only cover one element. Then the measured heat is only originated from one element.

As shown in FIG. 2, in an embodiment the sensor 20 comprises a heat sink 23. In an embodiment the heat sink 23 is coupled to the radiation absorber 21. In an embodiment the radiation absorber 21 is coupled to the heat sink 21 via a thermal link 24. In an embodiment the thermal link 24 is a weak thermal link. In an embodiment the thermal link 24 comprises at least one lowly thermally conductive material, such as stainless steel, epoxy and quartz.

By providing that the thermal link 24 is a weak thermal link, the radiation absorbed by the radiation absorber 21 may be converted into heat that raises the temperature of the radiation absorber 21 without a significant amount of the heat being transferred away from the radiation absorber 21 before its temperature can increase. By providing a coupled heat sink 23, the temperature of the radiation absorber 21 may be stabilised. For example, in between measurements of temperature changes of the radiation absorber 21, the heat sink 23 may help the radiation absorber 21 to return to a stable and known temperature. This may help to improve the reliability of measurements of the energy of EUV radiation. During the sensor measurement period (expected to be in a time scale of minutes), the absorbed EUV energy will not be dissipated; whereas after a long idle time, the temperature of the sensor 20 reaches an equilibrium with the heat sink 23.

In an embodiment the heat sink 23 comprises a highly thermally conductive material. In an embodiment the heat sink 23 comprises or consists of a material selected from the group consisting of copper, aluminum, silver, gold, diamond, aluminum nitride, silicon carbide, tungsten and graphite.

The energy of the non-EUV radiation may be measured based on measurements using the radiation transmitted through the reflectors 30 and separately from measurements associated with radiation transmitted through the EUV filter 22. Initially, it may be expected that the calculation of the energy of the non-EUV radiation derived from the reflectors 30 may be substantially the same as that derived from the EUV filter 22. However, over time calculations of the energy of non-EUV radiation derived from the reflectors 30 may differ from calculations derived from the EUV filter 22. This is because the sensor 20 may degrade over time. In an embodiment, the controller 50 is configured to compare the calculated energy of non-EUV radiation based on transmission through the reflectors 30 to the calculation of non-EUV radiation based on radiation transmitted through the EUV filter 22. By comparing the two calculated results, the controller 50 may output data from which it may be determined to what extent the sensor 20 has degraded. An embodiment of the invention is expected to make it easier to know when the sensor 20 needs to be recalibrated or replaced.

In an embodiment the calculator is configured to calculate a dose of EUV radiation based on the calculated energy Q of EUV radiation and dimensions of the radiation absorber. For example, the dose of EUV radiation may be calculated using the following formula.

Dose=Q/(L×W) where L and W are the length and width of a rectangular shaped radiation absorber 21.

In an embodiment, the calculated dose may be used to calibrate the value of the dose of the lithographic apparatus LA. In an embodiment, one or more other sensors of the lithographic apparatus LA may be calibrated based on the calculated dose calculated using the sensor 20. This process may be referred to as sensor matching.

An embodiment of the invention is expected to measure dose more accurately. An alternative dose measurement in a lithographic apparatus uses a photodiode, which converts photo energy into electrical signal. However, a photodiode cannot measure the absolute value of light intensity because the filter stack attenuates the incident light intensity reaching the photodiode. Moreover, the stability of photosensitivity of a photodiode suffers from contamination, which requires frequent calibration. In contrast the invention allows measurement of the dose without such attenuation and loss of stability due to contamination.

An alternative dose calibration method may use a wafer coated with photoresist which is exposed to EUV light as an external reference. The method then uses an alignment sensor to read alignment offset of a post exposure baked wafer or a level sensor to read resist height of a developed wafer. However, the method suffers from significant errors originating from wafer processing, measurements, and fitting of measured result with a calibration curve derived from limited number of measurements. In contrast the invention allows more accurate dose measurement without requiring such wafer processing. By correlating dose with a physical parameter that can be measured accurately, e.g. temperature, the absorbed EUV energy can be determined more accurately.

FIG. 7 is a schematic plan view of a substrate table WT. As shown in FIG. 7, in an embodiment the substrate table WT is provided with at least one sensor. As shown in FIG. 7, in an embodiment the sensor is located radially outward of the substrate W. in an embodiment, a plurality of sensors 20 are provided in the substrate table WT. By providing the sensors 20 at the substrate table WT, the sensor 20 may determine the energy of EUV radiation that reaches the level of the substrate W. This may help to improve the accuracy of the measurement of energy of EUV radiation that reaches the substrate W.

However, it is not essential for the sensor 20 to be located at the substrate level. Additionally or alternatively, the sensor 20 may be located at other positions along the optical path between the radiation source SO and the substrate table WT. For example, in an embodiment the lithographic apparatus LA comprises at least one sensor 20 at or near the intermediate focus point (i.e. where the radiation beam B enters the illumination system IL shown in FIG. 1). In an embodiment a sensor 20 is provided at or near the faceted field mirror device 10. In an embodiment at least one sensor 20 is provided at or near the faceted pupil mirror device 11. In an embodiment at least one sensor 20 is provided at or near the support structure MT. In an embodiment at least one sensor is provided at or near at least one of the plurality of mirrors 13, 14 of the projection system PS. An embodiment of the invention is expected to enable monitoring of the system power degradation at one or more modules of the lithographic apparatus LA. In an embodiment the sensor 20 is provided substantially coplanar with the substrate W.

The radiation may enter the surface 40 via only one portion of the surface 40 (e.g. via the exposed portion 42 or via the filter portion 41 or via a portion corresponding to the location of one of the reflectors 30). Once the radiation has been received via the portion of the surface 40, the radiation may dissipate through the radiation absorber 21. As a result, the dissipation may raise the temperature of the whole surface or whole of the radiation absorber 21.

As shown in FIG. 2, in an embodiment the EUV filter 22 is coupled to the heat sink 23. The heat sink 23 may be coupled to the EUV filter 22 via a thermal link 25. The heat sink 23 may be configured to stabilise the temperature of the EUV filter 22. The EUV filter 22 may heat up due to absorbing radiation (particularly non-EUV radiation) of the combined radiation 15.

In an embodiment the sensor 20 is connected to a power source by an electrical connection. For example, the sensor 20 may be connected to a power source via one or more wires. However, it is not essential for the sensor 20 to be connected via a wire to the power source. Additionally or alternatively, the sensor 20 may comprise a battery. The battery may be configured to be the power supply for the sensor 20. This may help with locating the sensor 20 in positions where it could otherwise be difficult to electrically connect the sensor 20 to the power source. For example, when the sensor 20 is located in the projection system or in the illumination system IL, it may be advantageous to provide the sensor 20 with a battery. In an embodiment the battery comprises a solid electrolyte. Such a solid electrolyte may make the battery more robust in the environment of the EUV lithographic apparatus LA.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A sensor for measuring energy of EUV radiation from combined radiation comprising EUV radiation and non-EUV radiation, the sensor comprising:
a radiation absorber configured to absorb radiation derived from the combined radiation via a surface of the radiation absorber;
a first reflector having a first reflectivity to EUV radiation configured to modify the combined radiation entering the surface;
a second reflector having a second reflectivity to EUV radiation configured to modify the combined radiation entering the surface, the second reflectivity being different from the first reflectivity;
a thermometer configured to measure a temperature change of the radiation absorber; and
a calculator configured to calculate the energy of EUV radiation based on a first temperature change associated with the combined radiation modified by the first reflector and a second temperature change associated with the combined radiation modified by the second reflector.

2. The sensor of claim 1, wherein the first and second reflectors comprise different topologies.

3. The sensor of claim 1 or 2, wherein the first and second reflectors comprise respective gratings.

4. The sensor of claim 3, wherein the gratings comprise a plurality of levels at different distance from the surface.

5. (canceled)

6. The sensor of claim 1, wherein the first reflector comprises an EUV reflection layer configured to reflect EUV radiation and the second reflector comprises an EUV reflection layer having a similar composition and/or thickness as the EUV reflection layer of the first reflector.

7. The sensor of claim 1, further comprising a heater configured to heat the radiation absorber independently of the combined radiation.

8. The sensor of claim 7, wherein the calculator is configured to calibrate calculation of the energy of EUV radiation based on heat output by the heater and a calibration temperature change associated with the heat from the heater.

9. The sensor of claim 1, further comprising an EUV filter different from the first reflector and the second reflector and configured to filter out the non-EUV radiation from the combined radiation such that filtered radiation is incident on a filter portion of the surface.

10. The sensor of claim 9, wherein the calculator is configured to calculate the energy of EUV radiation based on a filter temperature change associated with the filtered radiation.

11. The sensor of claim 1, arranged such that the combined radiation is incident on an exposed portion of the surface.

12. (canceled)

13. The sensor of claim 1, wherein the first reflector is provided at a first reflector region of the surface and the second reflector is provided at a second reflector region of the surface.

14. The sensor of claim 1, wherein the calculator is configured to calculate the energy of EUV radiation based on the first temperature change, the first reflectivity, the second temperature change and the second reflectivity.

15. The sensor of claim 1, further comprising a heat sink coupled to the radiation absorber configured to stabilise a temperature of the radiation absorber.

16. The sensor of claim 1, wherein the calculator is configured to calculate a dose of EUV radiation based on the calculated energy of EUV radiation and dimensions of the radiation absorber.

17.-18. (canceled)

19. A substrate table for an EUV lithographic apparatus configured to support a substrate, the substrate table comprising the sensor of claim 1.

20. The substrate table of claim 19, wherein the sensor is provided substantially coplanar with the substrate.

21. An EUV lithographic apparatus configured to direct patterned EUV radiation onto a substrate, the EUV lithographic apparatus comprising the sensor of claim 1.

22. The EUV lithographic apparatus of claim 21, configured to direct the patterned EUV radiation along a beam path onto the substrate, wherein the sensor is provided on the beam path upbeam of the substrate.

23. A method for measuring with the sensor of claim 1, energy of EUV radiation from combined radiation comprising EUV radiation and non-EUV radiation, the method comprising:
modifying the combined radiation entering a surface of the radiation absorber of the sensor with the first reflector having a first reflectivity to EUV radiation;
measuring, with the thermometer of the sensor, a first temperature change of the radiation absorber associated with the combined radiation modified by the first reflector;
modifying the combined radiation entering the surface with the second reflector of the sensor having a second reflectivity to EUV radiation, the second reflectivity being different from the first reflectivity;
measuring, with the thermometer, a second temperature change of the radiation absorber associated with the combined radiation modified by the second reflector; and
calculating the energy of EUV radiation based on the first temperature change and the second temperature change.

24. The method of claim 23, wherein the first and second reflectors comprise different topologies.

25.-38. (canceled)
